(19) United States
(12) Patent Application Publication
(10) Pub. No.: US 2015/0136731 A1
(43) Pub. Date: May 21, 2015

(54) DURABLE SOLAR MIRROR FILMS

(71) Applicant: 3M INNOVATIVE PROPERTIES COMPANY, SAINT PAUL, MN (US)

(72) Inventors: Attila Molnar, Vadnais Heights, MN (US); Andrew J. Henderson, Eagan, MN (US); Joseph H. Eaton, Eagan, MN (US); Ralph Gielissen, Dusseldorf (DE); Daniel T. Chen, Saint Paul, MN (US); Mark B. O'Neill, Stillwater, MN (US)

(21) Appl. No.: 14/398,483

(22) PCT Filed: Apr. 22, 2013
(86) PCT No.: PCT/US2013/037562

§ 371 Date: Nov. 3, 2014

Related U.S. Application Data
(60) Provisional application No. 61/642,250, filed on May 3, 2012.

(51) Int. Cl. H01L 31/18; C23F 4/00; H01L 31/054

(52) U.S. Cl. CPC H01L 31/18; H01L 31/0547; C23F 4/00
USPC 216/24; 205/221

(57) ABSTRACT

The present disclosure generally relates to durable solar mirror films, methods of making durable solar mirror films, and constructions including durable solar mirror films. Some embodiments of the present disclosure relate to methods of making solar mirror films that do not include a reflective layer material across the entire weatherable layer. Some embodiments relate to a method of making a solar mirror film involving providing a weatherable layer having a first major surface and a second major surface; depositing a reflective material on the first major surface of the weatherable layer; and removing a portion of the reflective material (e.g., ultrasonically, mechanically, or thermally).

### GOVERNMENT LICENSE RIGHTS

The Government of the United States of America has rights in at least some of the inventions described in this patent application pursuant to DE-AC36-08GO28308 (CRADA No. 08-316) awarded by the U.S. Department of Energy.

### TECHNICAL FIELD

The present disclosure generally relates to durable solar mirror films, methods of making durable solar mirror films, and constructions including durable solar mirror films.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources. One of the promising energy resources today is sunlight. Globally, millions of households currently obtain power from solar photovoltaic systems.

In general, concentrated solar technology involves the collection of solar radiation in order to directly or indirectly produce electricity. The three main types of concentrated solar technology are concentrated photovoltaic, concentrated solar power, and solar thermal.

In concentrated photovoltaic (CPV), concentrated sunlight is converted directly to electricity via the photovoltaic effect. Generally, CPV technology uses optics (e.g. lenses or mirrors) to concentrate a large amount of sunlight onto a small area of a solar photovoltaic material to generate electricity. CPV systems are often much less expensive to produce than other types of photovoltaic energy generation because the concentration of solar energy permits the use of a much smaller number of the higher cost solar cells.

In concentrated solar power (CSP), concentrated sunlight is converted to heat, and then the heat is converted to electricity. Generally, CSP technology uses mirrored surfaces in multiple geometries (e.g., flat mirrors, parabolic dishes, and parabolic troughs) to concentrate sunlight onto a receiver. That, in turn, heats a working fluid (e.g. a synthetic oil or a molten salt) or drives a heat engine (e.g., steam turbine). In some cases, the working fluid is what drives the engine that produces electricity. In other cases, the working fluid is passed through a heat exchanger to produce steam, which is used to power a steam turbine to generate electricity.

Solar thermal systems collect solar radiation to heat water or to heat process streams in industrial plants. Some solar thermal designs make use of reflective mirrors to concentrate sunlight onto receivers that contain water or the feed stream. The principle of operation is very similar to concentrated solar power units, but the concentration of sunlight, and therefore the working temperatures, are not as high.

The rising demand for solar power has been accompanied by a rising demand for reflective devices and materials capable of fulfilling the requirements for these disclosures. Some of these solar reflector technologies include glass mirrors, aluminized mirrors, and metalized polymer films. Of these, metalized polymer films are particularly attractive because they are lightweight, offer design flexibility, and potentially enable less expensive installed system designs than conventional glass mirrors. Polymers are lightweight, inexpensive, and easy to manufacture. In order to achieve metal surface properties on a polymer, thin layers of metal (e.g. silver) are coated on the polymer surface.

One exemplary commercially available solar mirror film is shown schematically in FIG. 1. The solar mirror film 100 of FIG. 1 includes a premask layer 110, a weatherable layer 120 (including, for example, a polymer), a thin, sputter-coated tie layer 140, a reflective layer 150 (including, for example, a reflective metal such as silver), a corrosion resistant layer 160 (including, for example, a metal such as copper), an adhesive layer 170, and a liner 180. The film of FIG. 1 is typically applied to a support substrate by removing liner 180 and placing adhesive layer 170 adjacent to the support substrate. Premask layer 110 is then removed to expose weatherable layer 120 to sunlight.

### SUMMARY

The metalized polymer films used in concentrated solar power units and concentrated photovoltaic solar systems are subject to continuous exposure to the elements. Consequently, a technical challenge in designing and manufacturing metalized polymer reflective films is achieving long-term (e.g., 20 years) durability when subjected to harsh environmental conditions. There is a need for metalized polymer films that provide durability and retained optical performance (e.g., reflectivity) once installed in a concentrated solar power unit or a concentrated photovoltaic cell. Mechanical properties, optical clarity, corrosion resistance, ultraviolet light stability, and resistance to outdoor weather conditions are all factors that can contribute to the gradual degradation of materials over an extended period of operation.

The inventors of the present disclosure recognized that many of the technical problems in forming a durable metalized polymer film capable of long-term outdoor use that retains its optical performance arise from the fundamental mismatch in the physical and chemical nature and properties of metals and polymers. One particular difficulty relates to ensuring good adhesion between the polymer layer and the metal reflective surface. Without good adhesion between these layers, delamination occurs. Delamination between the polymer layer and the metal layer is often referred to as “tunneling.”

The inventors of the present disclosure recognized that the delamination typically results from the decreased adhesion between the polymer layer and the metal layer. This decreased adhesion can be caused by any of numerous factors—and often a combination of these factors. Some exemplary factors that the inventors of the present disclosure recognized include (1) increased mechanical stress between the polymer layer and the metal layer; (2) oxidation of the metal layer; (3) oxidation of an adhesive adjacent to the metal layer; and (4) degradation of the polymer layer (this can be due to, for example, exposure to sunlight). Each of these factors can be affected by numerous external conditions, such as, for example, environmental temperature (including variations in environmental temperatures), thermal shock, humidity, exposure to moisture, exposure to air impurities such as, for example, salt and sulfur, UV exposure, product handling, and product storage.

One of the most challenging problems is related to stress at the metal/polymer interface. Once the stress becomes too great, buckling can occur, causing the polymer layer to delaminate from the metal layer. Further, when metalized polymer films are cut, their edges may be fractured and unprotected. Corrosion of metalized polymers begins at their edges, so this combination of fractured, exposed metal edges with the net interfacial stresses listed above can overcome adhesion strength and cause tunneling. The inventors of the present invention recognized the importance of protecting the interface between the polymer layer and the metal layer—especially along the edges of this interface.

Two prior art approaches have been used to address these problems. First, a sealing caulk has been applied around the edges of the metalized film. Second, a tape has been wrapped around the edges of the metalized film. Both approaches are effective at minimizing short-term delamination and/or tunneling, if properly applied. However, both approaches disadvantageously reduce the total available reflective area. Also, both approaches disadvantageously introduce a separate material to the front surface of the metalized film, which results in the creation of a ridge or protrusion above and below the plane of the metalized film. These ridges or protrusions are areas of potential additional stress when the metalized film is exposed to, for example, wind and hail. The additional stress is increased during routine maintenance processes including, for example, cleaning (e.g. pressure washing) and handling during disclosure. Also, in order to be effective over the lifetime of the metalized film (e.g., 20 years), the separate material must adhere to the metalized film for the lifetime of the film. These materials have limited ability to do so.

The inventors of the present disclosure recognized that the reflective layer in existing solar mirror films extends across the entire weatherable layer. As discussed above, the mismatch in properties of these layers make their interface prone to delamination and tunneling—especially at the edges of the mirror film. Thus, the inventors of the present disclosure recognized that a solar mirror film with less or no silver along some or all of the edges of the solar mirror film exhibits increased durability and decreased delamination and/or tunneling.

The inventors of the present disclosure also discovered new ways to form solar mirror films having less, minimal, or no reflective material in the edge portions. For example, the inventors of the present disclosure discovered a unique way to use ultrasonic welding to form a solar mirror film as described herein.

One embodiment of the present disclosure relates to a method of making a solar mirror film comprising: providing a weatherable layer having a first major surface and a second major surface; depositing a reflective material on the first major surface of the weatherable layer; and ultrasonically removing a portion of the reflective material.

Another embodiment of the present disclosure relates to a method of making a solar mirror film comprising: providing a weatherable layer having a first major surface and a second major surface; depositing a reflective material on the first major surface of the weatherable layer; and thermally removing a portion of the reflective material.

In some embodiments, the portion of the reflective material that is removed from the weatherable layer is along one or more edge regions of the weatherable layer. In some embodiments, at least one of the edge regions extends from the terminal edge of the weatherable layer to 2 mm onto the first major surface. In some embodiments, the edge region extends from the terminal edge of the weatherable layer to between about 2 mm and about 20 mm onto the first major surface.

In some embodiments, depositing the reflective material involves at least one of physical vapor deposition via sputter coating, evaporation via e-beam or thermal methods, ion-assisted e-beam evaporation, electro-plating, spray painting, vacuum deposition, and combinations thereof. In some embodiments, the reflective material covers at least 98% of the first major surface of the weatherable layer.

In some embodiments, ultrasonically removing the reflective material involves using a knurl pattern. In some embodiments, the method further comprises: ultrasonically removing a portion of the weatherable layer.

In some embodiments, the method further comprises placing a filler in the area from which the reflective material was removed. In some embodiments, the filler is a polymeric material. In some embodiments, the filler is a thermoplastic material.

In some embodiments, the weatherable layer includes at least one of PMMA, polycarbonate, polyester, multilayer optical film, fluoropolymer, and a blend of an acrylate and a fluoropolymer. In some embodiments, the reflective material includes at least one of silver, gold, aluminum, copper, nickel, and titanium.

In some embodiments, the method further comprises placing a tie layer between the weatherable layer and the reflective material. In some embodiments, the tie layer includes an adhesive. In some embodiments, the method further comprises ultrasonically removing a portion of the tie layer.

In some embodiments, the method further comprises placing a polymeric material between the weatherable layer and the reflective material. In some embodiments, the method further comprises placing a corrosion protective layer adjacent to the reflective layer. In some embodiments, the corrosion protective layer comprises at least one of copper and an inert metal alloy.

In some embodiments, the method further comprises placing the solar mirror film in at least one of a concentrated photovoltaic system, a concentrated solar system, or a reflector assembly.

Another embodiment of the present disclosure relates to a concentrated solar power system including a solar mirror film as described herein, including, but not limited to, any of the embodiments described above.

Another embodiment of the present disclosure relates to a concentrated photovoltaic power system including a solar mirror film as described herein, including, but not limited to, any of the embodiments described above.

Various aspects and advantages of exemplary embodiments of the disclosure have been summarized. The above summary is not intended to describe each illustrated embodiment or every implementation of the present disclosure. The Drawings and the Detailed Description that follow more particularly exemplify the various embodiments disclosed herein. These and various other features and advantages will be apparent from a reading of the following detailed description.

### BRIEF DESCRIPTION OF DRAWINGS

FIG. 1 is a schematic view of a prior art solar mirror film.

FIG. 2 is a schematic top view of one exemplary embodiment of a solar mirror film in accordance with the present disclosure.

FIG. 3 is a schematic top view of another exemplary embodiment of a solar mirror film in accordance with the present disclosure.

FIG. 4 is a schematic top view of another exemplary embodiment of a solar mirror film in accordance with the present disclosure.

FIG. 5 is a schematic top view of another exemplary embodiment of a solar mirror film in accordance with the present disclosure.

### DETAILED DESCRIPTION

Some embodiments of the present disclosure include methods of thermally removing at least some of the reflective material on a weatherable layer. In some embodiments, portions of at least one of the tie layer and the weatherable layer are also removed. Exemplary methods of thermal removal include any thermal process including, but not limited to, ultrasonic removal (e.g, ultrasonic welding) and laser removal. Thermal removal processes also include processes that transfer energy via conduction, radiation, or convection.

Some embodiments of the present disclosure relate to methods of making solar mirror films that do not include a reflective layer material across the entire weatherable layer. Some embodiments of the present disclosure relate to methods of making a solar mirror film that does not include a reflective material on one or more of the edge portions of a solar mirror film. Some embodiments of the present disclosure relate to methods of making a solar mirror films having a reflective layer with discontinuities in the edge portion of the solar mirror film.

The methods described herein all provide a more durable solar mirror film. This increased durability is due, at least in part, to enhanced adhesion around the edges of the film as a result of the direct contact between the weatherable layer and the adhesive layer. Consequently, the incidence of delamination or tunneling is minimized Adhesion is enhanced for at least the reason that the weatherable layer bonds directly to a layer other than the reflective layer (typically a tie layer). The weatherable layer and the layer to which it adheres have a bond strength that is greater than the bond strength of the weatherable layer and reflective layer.

One exemplary embodiment is shown as a schematic top view in FIG. 2. Solar mirror film 200 of FIG. 2 includes a weatherable layer 210 including a bulk region 220 and four edge regions 230a, 230b, 230c, and 230d. A reflective material 240 is adjacent to bulk region 220 of weatherable layer 210. Reflective material 240 is largely (or substantially) absent from edge regions 230a, 230b, 230c, and 230d. Those of skill in the art will appreciate that the specific embodiment shown in FIG. 2 has reflective material 240 substantially absent from all four edge regions 230, but it is within the scope of the present disclosure to have reflective material 240 absent from only one or more of the edge regions. As used herein, the term “substantially absent” with respect to the reflective material being substantially absent from the edge region(s) refers to at least 97% of the specific edge region lacking reflective material.

As used herein, the term “edge region” refers to the area between one edge of a sheeting and the bulk region. The edge region can, but does not have to, run the entire length or width of the sheeting. The size of edge region may vary based on specific disclosures. However, the edge area may be of any size that is large enough to form a bond strength between the adhesive layer and the weatherable layer that exceeds the bond strength between the weatherable layer and the reflective layer.

FIG. 3 shows an embodiment in which not all four edge regions of a rectangular sheet are free of reflective material. Specifically, the schematic top view of FIG. 3 shows a solar mirror film 300 including a weatherable layer 210 including a bulk region 320 and an edge regions 330a and 330b. A reflective material 240 is adjacent to bulk region 320 of weatherable layer 210. Reflective material 240 is largely (or substantially) absent from edge regions 330a and 330b.

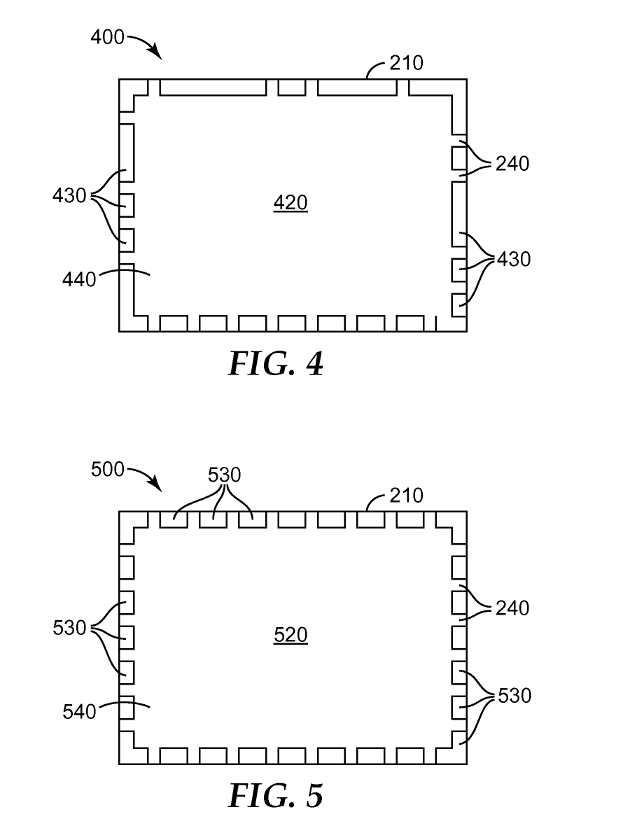

FIG. 4 shows an embodiment in which the edge regions do not run the entire length of the solar mirror film. Specifically, the schematic top view of FIG. 4 shows a solar mirror film 400 including a weatherable layer 210 including a bulk region 420 and numerous edge regions 430. A reflective material 240 is adjacent to bulk region 420 of weatherable layer 210. Reflective material 240 is largely (or substantially) absent from edge regions 430. As such, the reflective material is discontinuous along the edges of the sheet. The edge regions where the reflective material is substantially absent can be randomly sized (as shown, for example, in FIG. 4) or sized to form a pattern (as shown, for example, in FIG. 5). As such, the discontinuity can be patterned (for example, as shown in FIG. 4) or random (for example, as shown in FIG. 5).

FIG. 5 shows an embodiment in which the edge regions do not run the entire length of the solar mirror film. Specifically, the schematic top view of FIG. 5 shows a solar mirror film 500 including a weatherable layer 210 including a bulk region 520 and numerous edge regions 530. A reflective material 240 is adjacent to bulk region 520 of weatherable layer 210. Reflective material 240 is largely (or substantially) absent from edge regions 530. As such, the reflective material is discontinuous along the edges of the sheet.

For purposes of simplicity, the schematic views shown in FIGS. 2-5 only show the weatherable layer and the reflective material. These embodiments and this disclosure, however, is meant to include other layers in the solar mirror film, including, for example, layers between the weatherable layer and the reflective layer (e.g., a tie layer) and layers on top of or below the weatherable layer and/or the reflective layer. Each of the potential layers is described in greater detail below.

In some embodiments, the edge regions lacking reflective material are adjacent to (and in some cases, directly adjacent to) a tie layer or adhesive. In some embodiments, the edge regions lacking reflective material are adjacent to (and in some cases, directly adjacent to) a polymeric layer. Some exemplary polymeric layers include, for example, PMMA layer, PVDF layers, and blends thereof.

In some embodiments, removal of the reflective material creates a concave area. In some embodiments, this concave area is filled with a filler material. In some embodiments, the filler material is a polymer. In some embodiments, the polymer is a thermoplastic material.

Thermal removal of the reflective material can be effected by ultrasonic processes. In some embodiments, the ultrasonic process uses a knurl pattern. In some embodiments, the polymer material is heated by the absorbed vibration energy and the reflective material is dispersed. Ultrasonic heating can be applied over a range of pressures, frequencies, powers, and amplitudes. The amount of energy absorbed by the material depends on the process conditions, material's physical properties, nest (anvil) and sonotrode (horn) mechanical design. Anvil designs can vary in profile, width and materials. An advantage of ultrasonic processes is heat up and cool down times are relatively short compared to heated presses.

Thermal removal of the reflective material can be effected by laser ablation. In some embodiments, at low laser flux, the reflective material is heated by the absorbed laser energy and evaporates or sublimates. In some embodiments, at higher laser flux, the reflective material is converted to plasma. Laser ablation can use a pulsed laser or a continuous wave laser beam or a combination of both. The depth over which laser energy is absorbed, and thus the amount of material removed by a single laser pulse, depends on the material's optical properties and the laser wavelength. Laser pulses can vary over a very wide range of duration (milliseconds to femtoseconds) and fluxes. One advantage of using laser ablation is that laser output can be precisely controlled.

Premask Layer

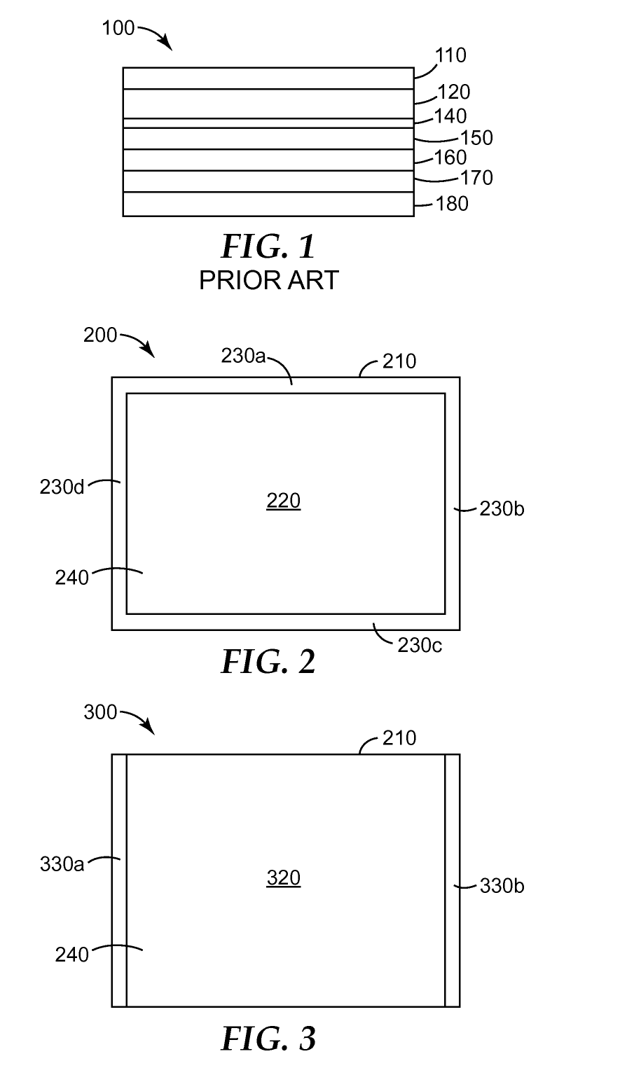

The premask layer is optional. Where present, the premask protects the weatherable layer during handling, lamination, and installation. Such a configuration can then be conveniently packaged for transport, storage, and consumer use. In some embodiments, the premask is opaque to protect operators during outdoor installations. In some embodiments, the premask is transparent to allow for inspection for defects. Any known premask can be used. One exemplary commercially available premask is ForceField® 1035 sold by Tredegar of Richmond, Va. Premask layer can be positioned, for example, as shown in FIG. 1.

Weatherable Layer

In some embodiments, the weatherable layer or sheet is flexible and transmissive to visible and infrared light. In some embodiments, the weatherable layer or sheet is resistant to degradation by ultraviolet (UV) light. In some embodiments, the phrase “resistant to degradation by ultraviolet light” means that the weatherable sheet at least one of reflects or absorbs at least 50 percent of incident ultraviolet light over at least a 30 nanometer range in a wavelength range from at least 300 nanometers to 400 nanometers. Photo-oxidative degradation caused by UV light (e.g., in a range from 280 to 400 nm) may result in color change and deterioration of optical and mechanical properties of polymeric films. In some embodiments, the weatherable sheet or layer is generally abrasion and impact resistant and can prevent degradation of, for example, solar assemblies when they are exposed to outdoor elements.

In some embodiments, the weatherable layer includes one or more organic film-forming polymers. Some exemplary polymers include, for examples, polyesters, polycarbonates, polyethers, polyimides, polyolefins, fluoropolymers, and combinations thereof. Assemblies according to the present disclosure include a weatherable sheet or layer, which can be a single layer (monolayered embodiments) or can include more than one layer (multilayered embodiments).

A variety of stabilizers may be added to the weatherable sheet to improve its resistance to UV light. Examples of such stabilizers include at least one of ultraviolet absorbers (UVA) (e.g., red shifted UV absorbers), hindered amine light stabilizers (HALS), or anti-oxidants. These additives are described in further detail below. In some of these embodiments, the weatherable sheet need not include UVA or HALS.

The UV resistance of the weatherable sheet can be evaluated, for example, using accelerated weathering studies. Accelerated weathering studies are generally performed on films using techniques similar to those described in ASTM G-155, “Standard practice for exposing non-metallic materials in accelerated test devices that use laboratory light sources.” One mechanism for detecting the change in physical characteristics is the use of the weathering cycle described in ASTM G155 and a D65 light source operated in the reflected mode. Under the noted test, and when the UV protective layer is applied to the article, the article should withstand an exposure of at least 18,700 kJ/m² at 340 nm before the b* value obtained using the CIE L*a*b* space increases by 5 or less, 4 or less, 3 or less, or 2 or less before the onset of significant cracking, peeling, delamination, or haze.

In some embodiments, the weatherable sheet includes a fluoropolymer. Fluoropolymers are typically resistant to UV degradation even in the absence of stabilizers such as UVA, HALS, and anti-oxidants. Some exemplary fluoropolymers include ethylene-tetrafluoroethylene copolymers (ETFE), ethylene-chloro-trifluoroethylene copolymers (ECTFE), tetrafluoroethylene-hexafluoropropylene copolymers (FEP), tetrafluoroethylene-perfluorovinylether copolymers (PFA, MFA) tetrafluoroethylene-hexafluoropropylene-vinylidene fluoride copolymers (THV), polyvinylidene fluoride homo and copolymers (PVDF), blends thereof, and blends of these and other fluoropolymers. Fluoropolymers typically comprise homo or copolymers of TFE, CTFE, VDF, HFP or other fully fluorinated, partially fluorinated or hydrogenated monomers such as vinyl ethers and alpa-olefins or other halogen containing monomers. The CTE of fluoropolymer films is typically high relative to films made from hydrocarbon polymers. For example, the CTE of a fluoropolymer film may be at least 75, 80, 90, 100, 110, 120, or 130 ppm/K. For example, the CTE of ETFE may be in a range from 90 to 140 ppm/K.

Weatherable films including fluoropolymer can also include non-fluorinated materials. For example, a blend of polyvinylidene fluoride and polymethyl methacrylate can be used. Useful flexible, visible and infrared light-transmissive substrates also include multilayer film substrates. Multilayer film substrates may have different fluoropolymers in different layers or may include at least one layer of fluoropolymer and at least one layer of a non-fluorinated polymer. Multilayer films can comprise a few layers (e.g., at least 2 or 3 layers) or can comprise at least 100 layers (e.g., in a range from 100 to 2000 total layers or more). The different polymers in the different multilayer film substrates can be selected, for example, to reflect a significant portion (e.g., at least 30, 40, or 50%) of UV light in a wavelength range from 300 to 400 rim as described, for example, in U.S. Pat. No. 5,540,978 (Schrenk). Such blends and multilayer film substrates may be useful for providing UV resistant substrates that have lower CTEs than the fluoropolymers described above.

Some exemplary weatherable sheets comprising a fluoropolymer can be commercially obtained, for example, from E.I. duPont De Nemours and Co., Wilmington, Del., under the trade designation “TEFZEL ETFE” and “TEDLAR,” and films made from resins available from Dyneon LLC, Oakdale, Minn., under the trade designations “DYNEON ETFE”, “DYNEON THV”, “DYNEON FEP”, and “DYNEON PVDF”, from St. Gobain Performance Plastics, Wayne, N.J., under the trade designation “NORTON ETFE”, from Asahi Glass under the trade designation “CYTOPS”, and from Denka Kagaku Kogyo KK, Tokyo, Japan under the trade designation “DENKA DX FILM.”

Some useful weatherable sheets are reported to be resistant to degradation by UV light in the absence of UVA, HALS, and anti-oxidants. For example, certain resorcinol isophthalate/terephthalate copolyarylates, for example, those described in U.S. Pat. Nos. 3,444,129; 3,460,961; 3,492,261; and 3,503,779 are reported to be weatherable. Certain weatherable multilayer articles containing layers comprising structural units derived from a 1,3-dihydroxybenzene organodicarboxylate are reported in Int. Pat. App. Pub. No. WO 2000/061664, and certain polymers containing resorcinol arylate polyester chain members are reported in U.S. Pat. No. 6,306,507. Block copolyestercarbonates comprising structural units derived from at least one 1,3-dihydroxybenzene and at least one aromatic dicarboxylic acid formed into a layer and layered with another polymer comprising carbonate structural units are reported in US Publication No. 2004/0253428. Weatherable sheets containing polycarbonate may have relatively high CTEs in comparison to polyesters, for example. The CTE of a weatherable sheet containing a polycarbonate may be, for example, about 70 ppm/K.

For some or all of the embodiments of the weatherable sheet or layer described above, the major surface of the weatherable sheet (e.g., fluoropolymer) can be treated to improve adhesion to a pressure sensitive adhesive. Useful surface treatments include, for example, electrical discharge in the presence of a suitable reactive or non-reactive atmosphere (e.g., plasma, glow discharge, corona discharge, dielectric barrier discharge or atmospheric pressure discharge); chemical pretreatment (e.g., using alkali solution and/or liquid ammonia); flame pretreatment; or electron beam treatment. A separate adhesion promotion layer may also be formed between the major surface of the weatherable sheet and the PSA. In some embodiments, the weatherable sheet may be a fluoropolymer that has been coated with a PSA and subsequently irradiated with an electron beam to form a chemical bond between the substrate and the pressure sensitive adhesive; (see, e.g., U.S. Pat. No. 6,878,400 (Yamanaka et al.). Some useful weatherable sheets that are surface treated are commercially available, for example, from St. Gobain Performance Plastics under the trade designation “NORTON ETFE”.

In some embodiments, the weatherable sheet has a thickness from about 0.01 mm to about 1 mm. In some embodiments, the weatherable sheet has a thickness from about 0.05 mm to about 0.25 mm. In some embodiments, the weatherable sheet has a thickness from about 0.05 mm to about 0.15 mm.

Tie Layer

In some embodiments, the tie layer includes a metal oxide such as aluminum oxide, copper oxide, titanium dioxide, silicon dioxide, or combinations thereof. As a tie layer, titanium dioxide was found to provide surprisingly high resistance to delamination in dry peel and wet peel testing. Further options and advantages of metal oxide tie layers are described in U.S. Pat. No. 5,361,172 (Schissel et al.), incorporated by reference herein.

In any of the foregoing exemplary embodiments, the tie layer has a thickness of equal to or less than 500 micrometers. In some embodiments, the tie layer has a thickness of between about 0.1 micrometer and about 5 micrometers. In some embodiments, it is preferable that the tie layer have an overall thickness of at least 0.1 nanometers, at least 0.25 nanometers, at least 0.5 nanometers, or at least 1 nanometer. In some embodiments, it is preferable that the tie layer have an overall thickness no greater than 2 nanometers, no greater than 5 nanometers, no greater than 7 nanometers, or no greater than 10 nanometers.

Reflective Layer/Reflective Material

The solar mirror films described herein include one or more reflective including one or more reflective materials. The reflective layer(s) (including reflective material) provide reflectivity. In some embodiments, the reflective layer(s) have smooth, reflective metal surfaces that are specular. As used herein, the term “specular surfaces” refer to surfaces that induce a mirror-like reflection of light in which the direction of incoming light and the direction of outgoing light form the same angle with respect to the surface normal. Any reflective metal may be used for this purpose, although preferred metals include silver, gold, aluminum, copper, nickel, and titanium. In some embodiments, the reflective layer includes silver.

Prior art reflective layers extend across the entire major surface of the weatherable layer. In the present disclosure, the reflective layer(s) do not extend across the entire major surface of the weatherable layer. Any method can be used to create a reflective layer that does not extend across the entire major surface of the weatherable layer.

In some embodiments, the reflective layer is deposited onto or otherwise positioned adjacent to the weatherable layer such that the reflective material does not extend across the entire major surface of the weatherable layer. In some embodiments, portions of the weatherable layer are masked during the deposition process such that the reflective layer is applied onto only a pre-determined portion of the compliant layer. U.S. patent Disclosure Matter No. 69866US002 (assigned to the assignee of the present disclosure) provides more detail on these methods and is incorporated herein by reference.

Alternatively or additionally, the reflective material may be deposited or positioned adjacent to the weatherable layer such that the reflective material extends across all or substantially all of the major surface of the weatherable layer and then portions of the reflective material are removed to form a reflective layer that does not extend across the entire major surface.

Disclosure of the reflective layer/the reflective material can be achieved using numerous coating methods including, for example, physical vapor deposition via sputter coating, evaporation via e-beam or thermal methods, ion-assisted e-beam evaporation, electro-plating, spray painting, vacuum deposition, and combinations thereof. The metallization process is chosen based on the polymer and metal used, the cost, and many other technical and practical factors. Physical vapor deposition (PVD) of metals is very popular for some disclosures because it provides the purest metal on a clean interface. In this technique, atoms of the target are ejected by high-energy particle bombardment so that they can impinge onto a substrate to form a thin film. The high-energy particles used in sputter-deposition are generated by a glow discharge, or a self-sustaining plasma created by applying, for example, an electromagnetic field to argon gas. In some embodiments, the reflective layer and/or reflective material is applied to a weatherable layer. In some embodiments (not shown in the figures), the reflective layer of reflective material is applied onto a tie layer.

Subsequent removal of portions of the reflective material can be effected in numerous ways including, for example, ultrasonically, using mechanical removal methods (including, for example, physical removal and laser removal), and using thermal removal methods. U.S. patent Disclosure Matter No. 69677US002 (assigned to the assignee of the present disclosure) provides more detail on these methods and is incorporated herein by reference.

The reflective material or layer(s) is preferably thick enough to reflect the desired amount of the solar spectrum of light. The preferred thickness can vary depending on the composition of the reflective layer and the specific use of the solar mirror film. In some exemplary embodiments, the reflective layer is between about 75 nanometers to about 100 nanometers thick for metals such as silver, aluminum, copper, and gold. In some embodiments, the reflective layer has a thickness no greater than 500 nanometers. In some embodiments, the reflective layer has a thickness of from 80 nm to 250 nm. In some embodiments, the reflective layer has a thickness of at least 25 nanometers, at least 50 nanometers, at least 75 nanometers, at least 90 nanometers, or at least 100 nanometers. Additionally, in some embodiments, the reflective layer has a thickness no greater than 100 nanometers, no greater than 110 nanometers, no greater than 125 nanometers, no greater than 150 nanometers, no greater than 200 nanometers, no greater than 300 nanometers, no greater than 400 nanometers, or no greater than 500 nanometers. Although not shown in the figures, two or more reflective layers may be used.

Corrosion Resistant Layer

The corrosion resistant layer is optional. Where included, the corrosion resistant layer may include, for example, elemental copper. Use of a copper layer that acts as a sacrificial anode can provide a reflective article with enhanced corrosion-resistance and outdoor weatherability. As another approach, a relatively inert metal alloy such as Inconel (an iron-nickel alloy) can also be used.

The corrosion resistant layer is preferably thick enough to provide the desired amount of corrosion resistance. The preferred thickness can vary depending on the composition of the corrosion resistant layer. In some exemplary embodiments, the corrosion resistant layer is between about 75 nanometers to about 100 nanometers thick. In other embodiments, the corrosion resistant layer is between about 20 nanometers and about 30 nanometers thick. Although not shown in the figures, two or more corrosion resistant layers may be used.

In some embodiments, the corrosion resistant layer has a thickness no greater than 500 nanometers. In some embodiments, the corrosion resistant layer has a thickness of from 80 nm to 250 nm. In some embodiments, the corrosion resistant layer has a thickness of at least 25 nanometers, at least 50 nanometers, at least 75 nanometers, at least 90 nanometers, or at least 100 nanometers. Additionally, in some embodiments, the corrosion resistant layer has a thickness no greater than 100 nanometers, no greater than 110 nanometers, no greater than 125 nanometers, no greater than 150 nanometers, no greater than 200 nanometers, no greater than 300 nanometers, no greater than 400 nanometers, or no greater than 500 nanometers.

Adhesive Layer

The adhesive layer is optional. Where present, the adhesive layer adheres the multilayer construction to a substrate (not shown in the figures). In some embodiments, the adhesive is a pressure sensitive adhesive. As used herein, the term “pressure sensitive adhesive” refers to an adhesive that exhibits aggressive and persistent tack, adhesion to a substrate with no more than finger pressure, and sufficient cohesive strength to be removable from the substrate. Exemplary pressure sensitive adhesives include those described in PCT Publication No. WO 2009/146227 (Joseph, et al.), incorporated herein by reference.

Liner

The liner is optional. Where present, the liner protects the adhesive and allows the solar mirror film to be transferred onto and another substrate. Such a configuration can then be conveniently packaged for transport, storage, and consumer use. In some embodiments, the liner is a release liner. In some embodiments, the liner is a silicone-coated release liner.

Substrate

The films described herein can be applied to a substrate by removing liner 180 (where present) and placing adhesive layer 170 (where present) adjacent to the substrate. Premask layer 110 (where present) is then removed to expose weatherable layer 120 to sunlight. Suitable substrates generally share certain characteristics. Most importantly, the substrate should be sufficiently rigid. Second, the substrate should be sufficiently smooth that texture in the substrate is not transmitted through the adhesive/metal/polymer stack. This, in turn, is advantageous because it: (1) allows for an optically accurate mirror, (2) maintains physical integrity of the metal reflective layer by eliminating channels for ingress of reactive species that might corrode the metal reflective layer or degrade the adhesive, and (3) provides controlled and defined stress concentrations within the reflective film-substrate stack. Third, the substrate is preferably nonreactive with the reflective mirror stack to prevent corrosion. Fourth, the substrate preferably has a surface to which the adhesive durably adheres.

Exemplary substrates for reflective films, along with associated options and advantages, are described in PCT Publication Nos. WO04114419 (Schripsema), and WO03022578 (Johnston et al.); U.S. Publication Nos. 2010/0186336 (Valente, et al.) and 2009/0101195 (Reynolds, et al.); and U.S. Pat. No. 7,343,913 (Neidermeyer), all of which are incorporated in their entirety herein. For example, the article can be included in one of the many mirror panel assemblies as described in co-pending and co-owned provisional U.S. patent Disclosure Ser. No. 13/393,879 (Cosgrove, et al.), incorporated herein in its entirety. Other exemplary substrates include metals, such as, for example, aluminum, steel, glass, or composite materials.

Advantages and embodiments of this disclosure are further illustrated by the following examples, but the particular materials and amounts thereof recited in these examples, as well as other conditions and details, should not be construed to unduly limit this disclosure. These examples are merely for illustrative purposes and are not meant to be limiting on the scope of the appended claims. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the disclosure of the doctrine of equivalents to the scope of the claims, each numerical parameter should at least be construed in light of the number of reported significant digits and by applying ordinary rounding techniques. Also, in these examples, all percentages, proportions and ratios are by weight unless otherwise indicated.

### EXAMPLES

### Test Methods

Neutral Salt Spray Test

Corrosion of the comparative examples and examples was evaluated following the procedure outlined on ISO 9227:2006, “Corrosion tests in artificial atmospheres—Salt spray tests” with the exception that results are reported as either % reflective area after various times in the salt spray or simply as visual observation failure while in the salt spray. Visual observation failure means the first visual sign of corrosion while the sample is in the salt spray.

Percent Reflective Area

The reflective area for each sample was taken as the surface area of the laminated samples that did not show any signs of discoloration due to corrosion or delamination. This area was then reported as a percent of the initial reflective surface area of the sample. The initial reflective area of the samples was taken as the full surface area of the control samples, and as the area within the ultrasonic seals for the ultrasonically edge treated samples. This was determined by making a photocopy of the laminates after testing and cutting out and weighing the black portions of the photocopy. The corroded areas appear non-black in the photocopy.

### Comparative Example 1

A reflective mirror film comprising a polymer layer and a metallized layer (obtained under the trade designation “SOLAR MIRROR FILM SMF-1100” from 3M Company, St. Paul, Minn.) was laminated onto a painted aluminum substrate having a thickness of approximately 0.02 in (0.05 cm) after removing the pressure sensitive adhesive liner on the metallized side. The aluminum substrate was then cut into 10.2 cm×10.2 cm (4 in×4 in) samples using a shear cutter. The premask was removed. The three samples were tested according to the “Neutral Salt Spray Test” described above. Test results are provided in Table 1.

An additional single (0.9 m×1.2 m) sample was exposed to the “Neutral Salt Spray Test” described above for a week and was then placed in sun and moisture for 2 months, after which 80% of the surface was covered with 1.3 cm (0.5 in) tunnels. This data is not reported in Table 1.

### Comparative Example 2

A reflective mirror film comprising a polymer layer and a metallized layer (obtained under the trade designation “SOLAR MIRROR FILM SMF-1100” from 3M Company, St. Paul, Minn.) was laminated onto a painted aluminum substrate having a thickness of approximately 0.02 in (0.05 cm) after removing the pressure sensitive adhesive liner on the metallized side. The aluminum substrate was then cut into 10.2 cm×10.2 cm (4 in×4 in) samples using a shear cutter. The premask was removed. All four edges of the sample were taped with 12.7 mm (0.5 in) wide “3M Weather Resistant Film Tape 838” (commercially available from 3M Company, St. Paul, Minn.) by adhering 6.4 mm (0.25 in) of the tape to the front side of the sample and around the edge face and tightly folding the remaining edge tape over the sample. The sample was tested according to the “Neutral Salt Spray Test” described above and showed signs of corrosion after two weeks.

### Example 1

A reflective mirror film comprising a polymer layer and a metallized layer (obtained under the trade designation “SOLAR MIRROR FILM SMF-1100” from 3M Company, St. Paul, Minn.) was laminated onto a painted aluminum substrate having a thickness of approximately 0.02 in (0.05 cm) after removing the pressure sensitive adhesive liner on the metallized side. The aluminum substrate was then cut into 10.2 cm×10.2 cm (4 in×4 in) samples using a shear cutter. The premask was removed.

Ultrasonic energy was used to weld the reflective mirror film along its edges as follows. An ultrasonic welder with a frequency of 20 kHz, power output of 4 kW, having a 3 in (7.62 cm) air cylinder (BRANSON model “2000X” commercially available from Emerson Industrial Automation, St. Louis, Mo.), a commercially available 1.5 gain titanium booster manufactured by Branson Company, and a titanium bar horn with 3.0 gain was used. This ultrasonic energy output corresponds to an amplitude of 89-99 micrometers (3.5-3.9 mils) peak to peak. The horn had a weld face of 15 cm×1.3 cm (6 in×0.5 in). The laminated aluminum samples were plunge welded using a pressure of 140 kPa (20 psi), a trigger force of 350 kPa (50 lb force), and a welding residence time of 0.15 sec on each of their four sides.

The sample was tested according to the “Neutral Salt Spray Test” described above and results are provided in Table 1.

### Example 2

A welded sample was prepared as described in Example 1, except that a pressure of 280 kPa (40 lb force) was used. The sample was tested according to the “Neutral Salt Spray Test” described above and results are provided in Table 1.

### Example 3

A welded sample was prepared as described in Example 1, except the polyolefin premask was not removed. All four sides of the 10.2 cm×10.2 cm (4 in×4 in) sample were welded at a distance of about 0.125 in (0.318 cm) from each edge at a pressure of 140 kPa (20 psi), trigger force of 350 kPa (50 lb force) and time duration of 0.15 sec on each side. The sample was tested according to the “Neutral Salt Spray Test” described above and results are provided in Table 1.

### Example 4

A laminated aluminum substrate was prepared as described in Example 3, except that a pressure of 240 kPa (35 psi) was used and the trigger force applied for 0.10 sec on each side of the sample. The sample was tested according to the “Neutral Salt Spray Test” described above and results are provided in Table 1.

### Example 5

A 254 micrometer (10 mil) thick polyvinylidenefluoride (PVDF) homopolymer film (obtained under the trade designation “SOLEF 1010” from Solvay Solexis, West Deptford, N.J.) was provided. The PVDF film cut to a width of about 0.1 cm was placed over the mirror film about 0.125 in (0.318 cm) from the edge. All four edges of the 10.2 cm×10.2 cm construction were welded using the ultrasonic welder described in Example 1 at a distance of about 3.18 mm (0.125 in) from each edge at a pressure of 480 kPa (70 psi) for all sides, a trigger force of 2100 kPa (300 lb force) for all sides and a time of 0.09 sec for all sides. Thus, a strip of PVDF film was aligned below the horn of the ultrasonic welder using this method and “melted” into the PMMA layer.

The sample was tested according to the “Neutral Salt Spray Test” described above and results are provided in Table 1.

### Example 6

A 254 micrometer (10 mil) cast film of an impact modified PMMA based resin was obtained by recommended industry extrusion conditions for such resins. The resin was obtained from Plaskolite, Columbus, Ohio (OPTIX CA-923 UVA2) and contained 15% of a 2-layer type impact modifier, 1.5% of a UV absorber, and had a melt flow rate of 2.0-3.0 (g/10 min, as per ASTM D 1238, (3.8/230)). The film was cut to a width of 0.1 cm and placed over the reflective mirror film side of the (10.2 cm×10.2 cm) laminated aluminum substrate and welded at a distance of about 3.18 mm (0.125 in) from each edge, using a pressure of 480 kPa (70 psi), trigger force of 2100 kPa (300 lb force) for, respectively, 0.09, 0.13, 0.10, 0.10 seconds for the first, second, third, and fourth sides. Two additional replicate samples (total of 3) were made and tested with the same salt spray test results as the first sample as reported for Example 6 in Table 1. The narrow impact modified PMMA strips were intended to fill in possible welding holes and protect against impacts and abuse although the examples tested were not submitted to abuse or impact.

The sample was tested as described in the “Neutral Salt Spray Test” and results are shown in Table 1.

### Example 7

A sample of the 10.2 cm×10.2 cm (4 in×4 in) laminate as described in Example 1 was made. The sample without the PSA and liner had all four metal edges manually mechanically scraped from the metal side of the laminate with a silicon carbide hand tool (12.7 mm (0.5 in) wide blade with square edge). The tool was used to remove 3.18 mm (0.125 in) of the silver from all 4 edges. Following this mechanical removal, an equivalent PSA was coated onto the scraped metal side of the laminate and the laminate was then adhered to the aluminum substrate as described under “Aluminum Substrate Preparation.”

The sample was tested as described in the “Neutral Salt Spray Test” and showed no signs of corrosion after 67 days.

An additional single (0.9 m×1.2 m) sample was exposed to the Neutral Salt Spray test described above for a week and was then exposed to sun and moisture for one year. Even after one year of such exposure, the sample showed no signs of tunneling. This data is not reported in Table 1.

### Example 8

A sample of the 10.2 cm×10.2 cm (4 in×4 in) laminate was made as described in Example 1. The sample was then laser ablated to create a 15 mm×15 mm square well about 12.7 mm-25.4 mm (0.5 in-1.0 in) from the edge of the laminate. The A SP-40P-HL laser from SPI Lasers was used in conjunction with a “hurrySCAN 20” scanner (commercially available from Scanlab AG, Munich, Germany) with telecentric F-Theta Objective (f=100 mm focal length). The scanner and laser were controlled by a computer. Settings included wavelength 1070 nm, pulse length 250 ns, speed 500 mm/sec and repetition rate 30 kHz. The laser maximum power was 40W although the actual power used in the example was 50% or 20 W. The laser orientation was through the PMMA side of the laminate. Single or triple width lines were produced by single or triple scans.

The sample was tested as described in the “Neutral Salt Spray Test” and showed signs of corrosion after 7 days.

### Example 9

A sample was made as described in Example 8 but was laser ablated at 60% power. The sample was tested as described in the “Neutral Salt Spray Test” and showed signs of corrosion after 21 days.

### Example 10

A sample was made as described in Example 8 but was laser ablated before lamination to the aluminum substrate. The sample was tested as described in the “Neutral Salt Spray Test” and showed no signs of corrosion after 9 days, at which point the test was stopped.

### Example 11

A sample was made as described in Example 10 but with 60% power. The samples were tested as described in the “Neutral Salt Spray Test” and showed no signs of corrosion after 9 days.

### Example 12

In addition to the ultrasonic examples 1-6, ultrasonic welding was also demonstrated using a knurled anvil. A few knurl patterns were tried and an optimized knurl pattern was determined to be one with a repeat pitch of 0.020 inch, an included angle of 90 degrees and a width of 0.64 cm (0.25 in). “SOLAR MIRROR FILM SMF-1100” film (not laminated to aluminum substrate) with the adhesive premask side facing the knurl patterned anvil was passed under a bar horn. The horn was vibrating at a frequency of 20 kHz. The weld face of the horn was 15 cm×2.5 cm (6 in×1 in). The horn has a radius of 6.22 cm (2.45 in) continuous across the 2.5 cm (1 in) weld face. Amplitude as measured at the weld face was 44.7 micrometers (1.76 mils) peak to peak which is 75% of the total output, speed of the film was 10.7 m/min (35 feet/min) and force was 667 N (150 lbf).

The samples were tested as described in the “Neutral Salt Spray Test” and showed less than 5% corrosion after 16 days.

### Example 13

A sample was made as described in Example 12 except the amplitude was 87.5% of the total output, the speed was 15 m/min (50 feet/min), and the force was 500 N (112.5 lbf). The samples were tested according to the “Neutral Salt Spray Test” and showed no signs of corrosion after 16 days.

### Example 14

A sample was made as described in Example 12 except the amplitude was 100% of the total output, the speed was 11 m/min (35 feet/min), and the force was 334 N (75 lbf). The samples were tested according to the “Neutral Salt Spray Test” and showed less than 5% corrosion after 16 days.

TABLE 1
Reflective Area and Visual Time to Failure Results

| Examples | Percent Reflective Area | Visual Time to Failure |
|---|---|---|
| Comparative | Sample 1: 5% after 11 days | Failed within 1 day |
| Example 1 | Sample 2: 5% after 11 days | |
| | Sample 3: 20% after 11 days | |
| Comparative | Not measured | Failed at 14 days |
| Example 2 | | |
| Example 1 | 100% after 31 days | Not measured |
| Example 2 | 100 after 31 days | Not measured |
| Example 3 | 95 after 11 days | Not measured |
| | 60 after 31 days | |
| Example 4 | 100 after 31 days | Not measured |
| Example 5 | 100 after 31 days | Not measured |
| Example 6 | 100 after 31 days | Not measured |
| Example 7 | Not measured | No sign of corrosion after |
| | | 67 days |
| Example 8 | Not measured | Failed at 7 days |
| Example 9 | Not measured | No sign of corrosion after |
| | | 21 days |
| Example 10 | Not measured | No sign of corrosion after 9 |
| | | days |
| Example 11 | Not measured | No sign of corrosion after 9 |
| | | days |
| Example 12 | Not measured | <5% corrosion after 16 |
| | | days |
| Example 13 | Not measured | No signs of corrosion after |
| | | 16 days |
| Example 14 | Not measured | <5% corrosion after 16 |
| | | days |

All references mentioned herein are incorporated by reference.

Unless otherwise indicated, all numbers expressing feature sizes, amounts, and physical properties used in the present disclosure and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this disclosure and the appended claims, the term “or” is generally employed in its sense including “and/or” unless the content clearly dictates otherwise.

Various embodiments and implementation of the present disclosure are disclosed. The disclosed embodiments are presented for purposes of illustration and not limitation. The implementations described above and other implementations are within the scope of the following claims. One skilled in the art will appreciate that the present disclosure can be practiced with embodiments and implementations other than those disclosed. Those having skill in the art will appreciate that many changes may be made to the details of the above-described embodiments and implementations without departing from the underlying principles thereof. It should be understood that this invention is not intended to be unduly limited by the illustrative embodiments and examples set forth herein and that such examples and embodiments are presented by way of example only with the scope of the invention intended to be limited only by the claims set forth herein as follows. Further, various modifications and alterations of the present invention will become apparent to those skilled in the art without departing from the spirit and scope of the present disclosure. The scope of the present disclosure should, therefore, be determined only by the following claims.

1. A method of making a solar mirror film comprising:
providing a weatherable layer having a first major surface and a second major surface;
depositing a reflective material on the first major surface of the weatherable layer; and
ultrasonically removing a portion of the reflective material.

2. The method of claim 1, wherein the portion of the reflective material that is removed from the weatherable layer is along one or more edge regions of the weatherable layer.

3. (canceled)

4. (canceled)

5. The method of claim 1, wherein depositing the reflective material involves at least one of physical vapor deposition via sputter coating, evaporation via e-beam or thermal methods, ion-assisted e-beam evaporation, electro-plating, spray painting, vacuum deposition, and combinations thereof.

6. The method of claim 1, wherein the reflective material covers at least 98% of the first major surface of the weatherable layer.

7. (canceled)

8. The method of claim 1, further comprising:
ultrasonically removing a portion of the weatherable layer.

9. (canceled)

10. (canceled)

11. (canceled)

12. The method of claim 1, wherein the weatherable layer includes at least one of PMMA, polycarbonate, polyester, multilayer optical film, fluoropolymer, and a blend of an acrylate and a fluoropolymer.

13. The method of claim 1, wherein the reflective material includes at least one of silver, gold, aluminum, copper, nickel, and titanium.

14. The method of claim 1, further comprising:
placing a tie layer between the weatherable layer and the reflective material.

15. (canceled)

16. (canceled)

17. (canceled)

18. The method of claim 1, further comprising:
placing a corrosion protective layer adjacent to the reflective layer.

19. (canceled)

20. The method of claim 1, further comprising:
placing the solar mirror film in at least one of a concentrated photovoltaic system, a concentrated solar system, or a reflector assembly.

21. A method of making a solar mirror film comprising:
providing a weatherable layer having a first major surface and a second major surface;
depositing a reflective material on the first major surface of the weatherable layer; and
thermally removing a portion of the reflective material.

22. The method of claim 21, wherein the portion of the reflective material that is removed from the weatherable layer is along one or more edge regions of the weatherable layer.

23. (canceled)

24. (canceled)

25. The method of claim 1, wherein depositing the reflective material involves at least one of physical vapor deposition via sputter coating, evaporation via e-beam or thermal methods, ion-assisted e-beam evaporation, electro-plating, spray painting, vacuum deposition, and combinations thereof.

26. The method of claim 1, wherein the reflective material covers at least 98% of the first major surface of the weatherable layer.

27. (canceled)

28. The method of claim 1, further comprising:
thermally removing a portion of the weatherable layer.

29. (canceled)

30. (canceled)

31. (canceled)

32. The method of claim 1, wherein the weatherable layer includes at least one of PMMA, polycarbonate, polyester, multilayer optical film, fluoropolymer, and a blend of an acrylate and a fluoropolymer.

33. The method of claim 1, wherein the reflective material includes at least one of silver, gold, aluminum, copper, nickel, and titanium.

34. The method of claim 1, further comprising:
a tie layer between the weatherable layer and the reflective material.

35. (canceled)

36. (canceled)

37. (canceled)

38. The method of claim 1, further comprising:
placing a corrosion protective layer adjacent to the reflective layer.

39. (canceled)

40. The method of claim 1, further comprising:
placing the solar mirror film in at least one of a concentrated photovoltaic system, a concentrated solar system, or a reflector assembly.
